(19) United States
(12) Patent Application Publication
(10) Pub. No.: US 2026/0141928 A1
(43) Pub. Date: May 21, 2026

(54) THREE-DIMENSIONAL SEMICONDUCTOR DEVICE

(71) Applicant: Samsung Electronics Co., Ltd., Suwon-si (KR)

(72) Inventor: Seoha LEE, Suwon-si (KR)

(21) Appl. No.: 19/328,401

(22) Filed: Sep. 15, 2025

(30) Foreign Application Priority Data
Nov. 20, 2024 (KR) 10-2024-0166520

(51) Int. Cl. G11C 5/06; H10B 12/00

(52) U.S. Cl. CPC G11C 5/063; H10B 12/482; H10B 12/488

(57) ABSTRACT

A three-dimensional semiconductor device may include a substrate, bit lines including a first bit line and a second bit line, which are spaced apart from and each other, semiconductor patterns on the bit lines, word lines on the semiconductor patterns and extending in the second direction, a first global bit line on the first bit line and extending in the third direction, a second global bit line on the second bit line and extending in the third direction, and a first via on a top surface of the second bit line and between the second bit line and the second global bit line. A distance from the bottom surface of the substrate in the first direction to a top surface of the first global bit line may be different from a that of a top surface of the second global bit line.

### CROSS-REFERENCE TO RELATED APPLICATIONS

This U.S. non-provisional patent application claims priority under 35 U.S.C. § 119 to Korean Patent Application No. 10-2024-0166520, filed on Nov. 20, 2024, in the Korean Intellectual Property Office, the entire contents of which are hereby incorporated by reference.

### TECHNICAL FIELD

The present disclosure relates to a three-dimensional semiconductor device.

### BACKGROUND

Due to their small-sized, multifunctional, and/or low-cost characteristics, semiconductor devices are important elements in the electronics industry. Semiconductor devices may be classified into a semiconductor memory device for storing data, a semiconductor logic device for processing data, and a hybrid semiconductor device including both of memory and logic elements.

With the recent trend of high speed and low power consumption of electronic devices, semiconductor devices in the electronic devices are also required to have high operating speeds and/or low operating voltages. In order to satisfy this requirement, it is necessary to increase an integration density of the semiconductor device. However, as the integration density of the semiconductor device increases, the semiconductor device may suffer from deteriorated electrical characteristics and low production yield. Accordingly, many studies are being conducted to improve the electrical characteristics and production yield of the semiconductor device.

### SUMMARY

Some embodiments of the inventive concept provides a semiconductor device with improved reliability.

According to some embodiments of the inventive concept, a three-dimensional (3D) semiconductor device may include a substrate, bit lines on the substrate, extending in a first direction perpendicular to a bottom surface of the substrate, and including a first bit line and a second bit line, which are spaced apart from and adjacent to each other in a second direction parallel to the bottom surface of the substrate, semiconductor patterns on the bit lines and extending in a third direction perpendicular to the first and second directions, word lines on the semiconductor patterns and extending in the second direction, a first global bit line on the first bit line and extending in the third direction, a second global bit line on the second bit line and extending in the third direction, and a first via on a top surface of the second bit line and between the second bit line and the second global bit line. A distance from the bottom surface of the substrate in the first direction to a top surface of the first global bit line may be different from a distance from the bottom surface of the substrate in the first direction to a top surface of the second global bit line.

According to some embodiments of the inventive concept, a three-dimensional (3D) semiconductor device may include a substrate, bit lines on the substrate, extending in a first direction perpendicular to a bottom surface of a substrate, and including a first bit line and a second bit line, which are spaced apart from each other in a second direction parallel to the bottom surface of the substrate, semiconductor patterns on the bit lines and extending in a third direction perpendicular to the first and second directions, word lines on the semiconductor patterns and extending in the second direction, a first global bit line on the first bit line and extending in the third direction, a second global bit line on the second bit line and extending in the third direction, and a via between the second bit line and the second global bit line and overlapped by the second bit line and the second global bit line in the first direction. The via may be a same distance from the bottom surface of the substrate in the first direction as a distance to the first global bit line and may be adjacent to the first global bit line in the second direction, and a distance from the bottom surface of the substrate in the first direction of a top surface of the via may be greater than a distance from the bottom surface of the substrate in the first direction of a top surface of the first global bit line.

According to some embodiments of the inventive concept, a three-dimensional (3D) semiconductor device may include a substrate, a first stack and a second stack, on the substrate and adjacent to each other in a first direction parallel to a bottom surface of the substrate, and a data storage pattern between the first stack and the second stack. Each of the first and second stacks may include bit lines extending in a second direction perpendicular to the bottom surface of the substrate and spaced apart from each other in a third direction perpendicular to the first and second directions, semiconductor patterns, on the bit lines and are extending in the first direction, and word lines on the semiconductor patterns and extending in the third direction. The 3D semiconductor device may further include global bit lines extending in the first direction and electrically connecting at least one of the bit lines of the first stack to at least one of the bit lines of the second stack, the global bit lines spaced apart from each other in the third direction. The global bit lines may include first global bit lines, and second global bit lines whose top surfaces are at a different distance from the bottom surface of the substrate in the first direction than from top surfaces of the first global bit lines. At least one of the first global bit lines may be adjacent to at least one of the second global bit lines in the third direction, and a distance from the bottom surface of the substrate in the first direction to a top surface of the data storage pattern may be greater than a distance from the bottom surface of the substrate in the first direction to top surfaces of the word lines.

### BRIEF DESCRIPTION OF THE DRAWINGS

FIG. 1 is a circuit diagram schematically illustrating a three-dimensional semiconductor device according to embodiments of the inventive concept.

FIGS. 2A, 2B, and 2C are perspective views schematically illustrating a three-dimensional semiconductor device according to embodiments of the inventive concept.

FIG. 3 is a perspective view illustrating semiconductor patterns, word lines, bit lines, global bit lines, and data storage pattern of a three-dimensional semiconductor device according to embodiments of the inventive concept.

FIG. 4 is a plan view illustrating a three-dimensional semiconductor device according to embodiments of the inventive concept.

FIG. 5A is a sectional view taken along a line A-A′ of FIG. 4.

FIG. 5B is a sectional view taken along a line B-B′ of FIG. 4.

FIG. 5C is a sectional view taken along a line C-C′ of FIG. 4.

FIG. 6 is a plan view illustrating a three-dimensional semiconductor device according to embodiments of the inventive concept.

FIG. 7 is a sectional view taken along a line C-C′ of FIG. 6.

FIG. 8 is a plan view illustrating a three-dimensional semiconductor device according to embodiments of the inventive concept.

FIG. 9A is a sectional view taken along a line C-C′ of FIG. 8.

FIG. 9B is a sectional view taken along a line D-D′ of FIG. 8.

FIG. 10 is a plan view illustrating a three-dimensional semiconductor device according to embodiments of the inventive concept.

FIG. 11 is a sectional view taken along a line D-D′ of FIG. 10.

FIGS. 12A, 12B, 12C, 13A, 13B, 13C, 14A, 14B, and 14C are diagrams illustrating a method of fabricating a three-dimensional semiconductor device, according to embodiments of the inventive concept.

### DETAILED DESCRIPTION

Example embodiments of the present disclosure will now be described more fully with reference to the accompanying drawings, in which example embodiments are shown.

The term “surrounding” or “covering” or “enclosing” as may be used herein may not require completely surrounding or covering or enclosing the described elements or layers, but may, for example, refer to partially surrounding or covering or enclosing the described elements or layers, for example, with voids or other spaces throughout. The term “and/or” includes any and all combinations of one or more of the associated listed items. The term “connected” may be used herein to refer to a physical and/or electrical connection.

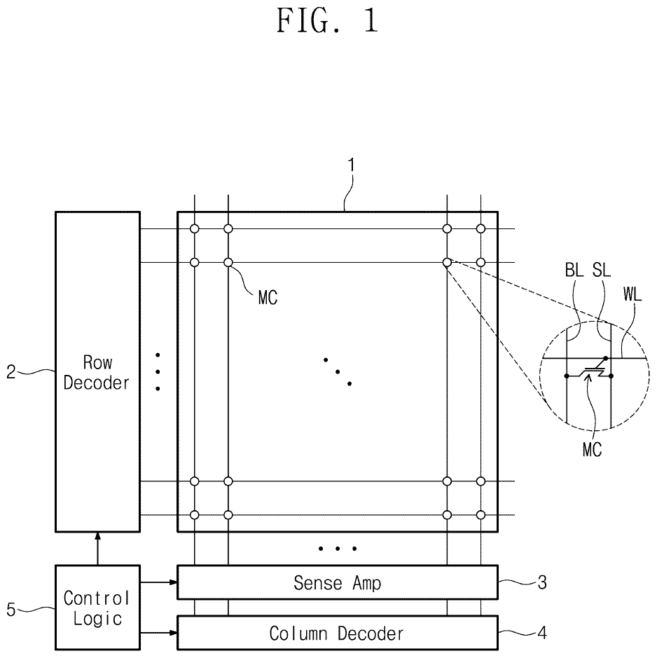

FIG. 1 is a circuit diagram schematically illustrating a three-dimensional semiconductor device according to an embodiment of the inventive concept.

Referring to FIG. 1, a three-dimensional semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three-dimensionally arranged, and each of the memory cells MC may be connected to one of the word lines WL, one of the bit lines BL, and one of the source lines SL. In some embodiments, each of the memory cells MC may be composed of one transistor including a memory layer or a data storing layer.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may establish a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

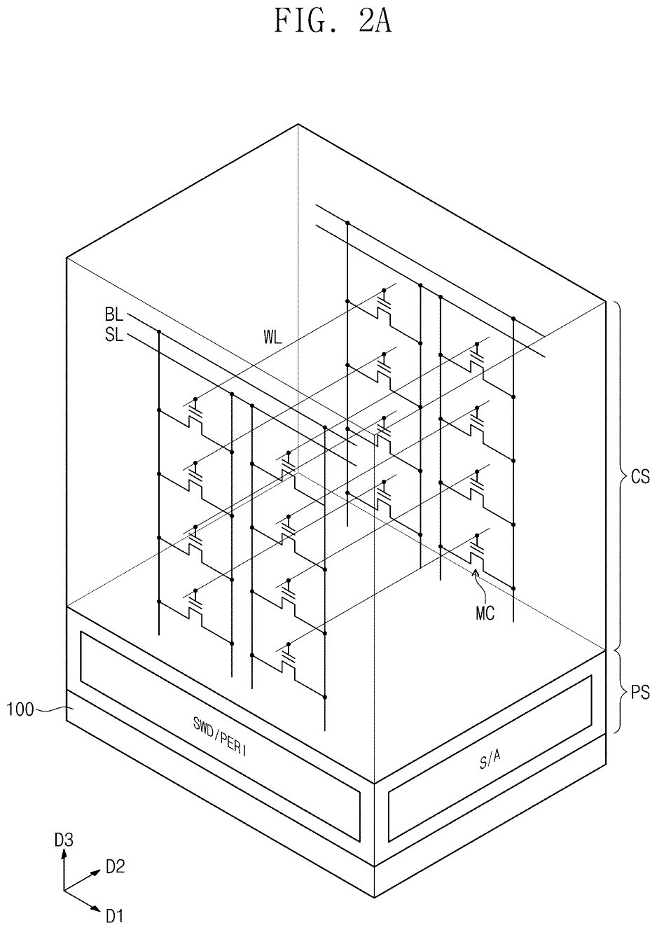

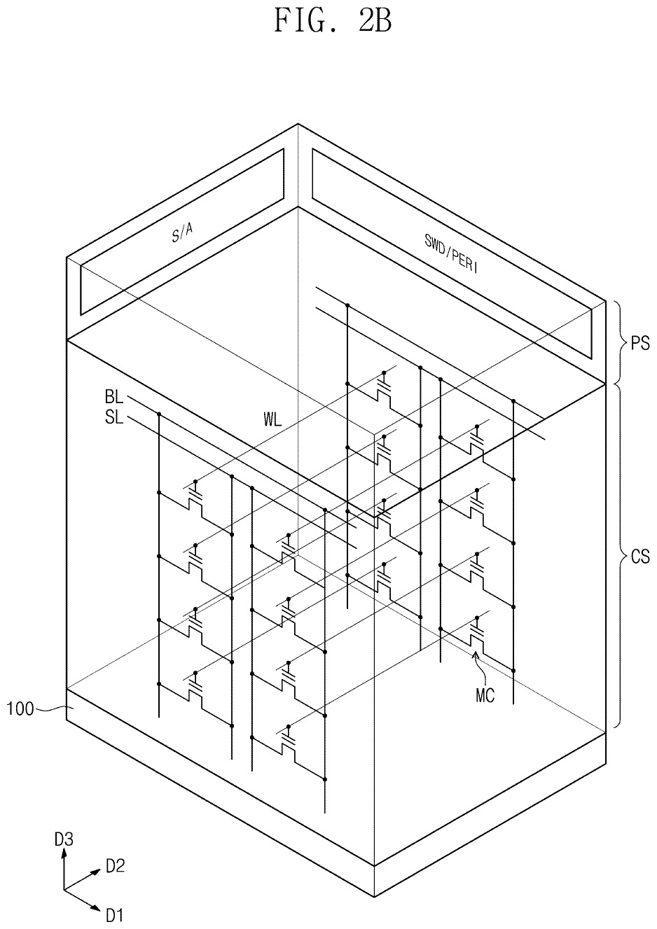

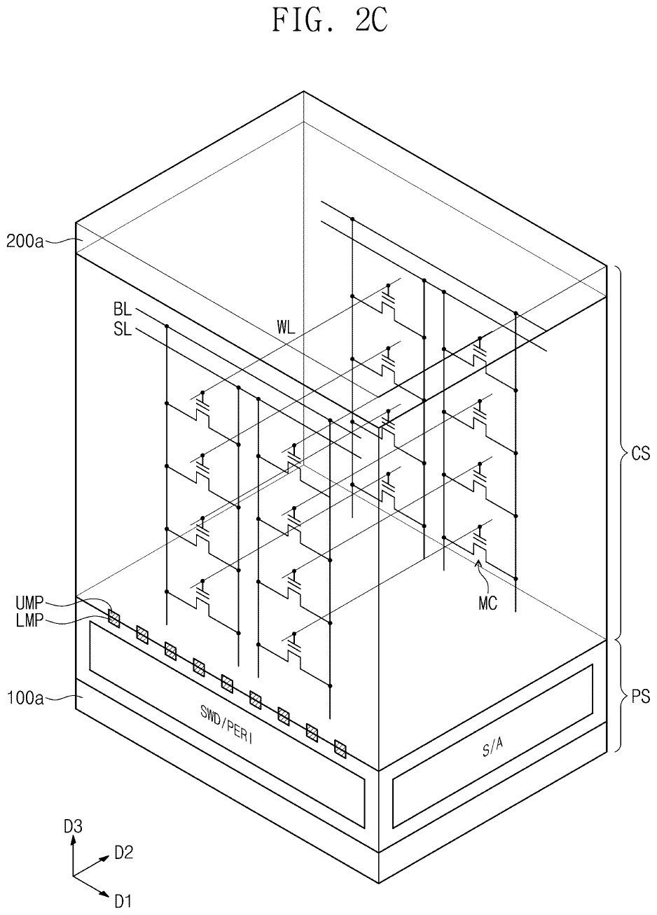

FIGS. 2A, 2B, and 2C are perspective views schematically illustrating a three-dimensional semiconductor device according to some embodiments of the inventive concept.

Referring to FIG. 2A, a three-dimensional semiconductor device may include a substrate 100, a peripheral circuit structure PS on the substrate 100, and a cell array structure CS on the peripheral circuit structure PS.

The peripheral circuit structure PS may include core and peripheral circuits, which are formed on the substrate 100. The core and peripheral circuits may include the row and column decoders 2 and 4, the sense amplifier 3, and the control logic 5 described with reference to FIG. 1.

The substrate 100 may be a plate-shaped structure that is extended parallel to a plane defined by a first direction D1 and a second direction D2. The first and second directions D1 and D2 may be parallel to a bottom surface of the substrate 100 and may not be parallel to each other. In some embodiments, the first and second directions D1 and D2 may be horizontal directions that are orthogonal to each other. The peripheral circuit structure PS and the cell array structure CS may be sequentially stacked on the substrate 100 in a vertical direction D3 perpendicular to the bottom surface of the substrate 100.

The cell array structure CS may include the bit lines BL, the source lines SL, the word lines WL, and the memory cells MC therebetween. Each of the memory cells MC may be connected to one of the word lines WL, one of the bit lines BL, and one of the source lines SL.

Referring to FIG. 2B, the semiconductor device may include the cell array structure CS on the substrate 100 and the peripheral circuit structure PS on the cell array structure CS. The cell array structure CS may be disposed between the substrate 100 and the peripheral circuit structure PS. The peripheral circuit structure PS may include the core and peripheral circuits.

Referring to FIG. 2C, the semiconductor device may have a chip-to-chip (C2C) structure. The peripheral circuit structure PS may include a first substrate 100a. Lower metal pads LMP may be provided in the uppermost portion of the peripheral circuit structure PS. The lower metal pads LMP may be electrically connected to the core and peripheral circuits. The lower metal pads LMP may be bonded to upper metal pads UMP of the cell array structure CS.

The cell array structure CS may include a second substrate 200a, and the upper metal pads UMP may be provided in the lowermost portion of the cell array structure CS. The upper metal pads UMP may be electrically connected to the bit lines BL, the source lines SL, and the word lines WL. The upper metal pads UMP may be electrically connected to the memory cells MC.

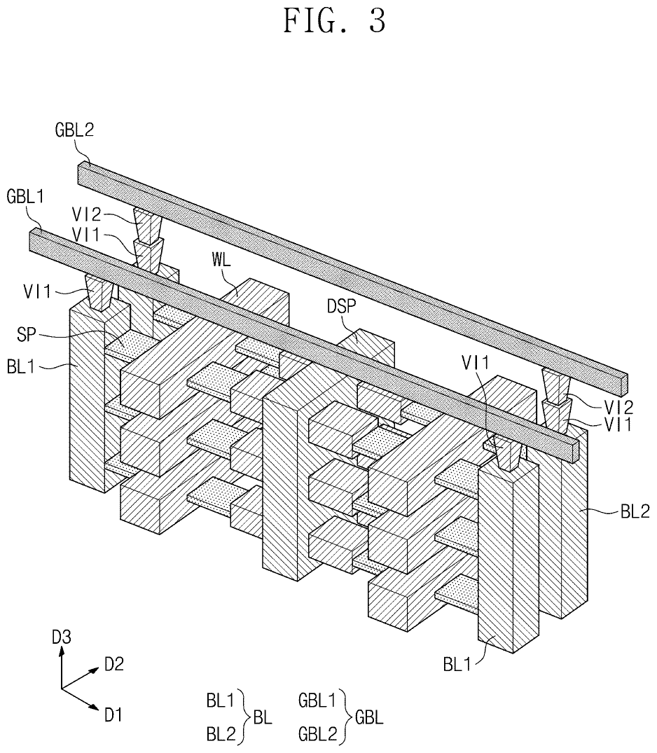

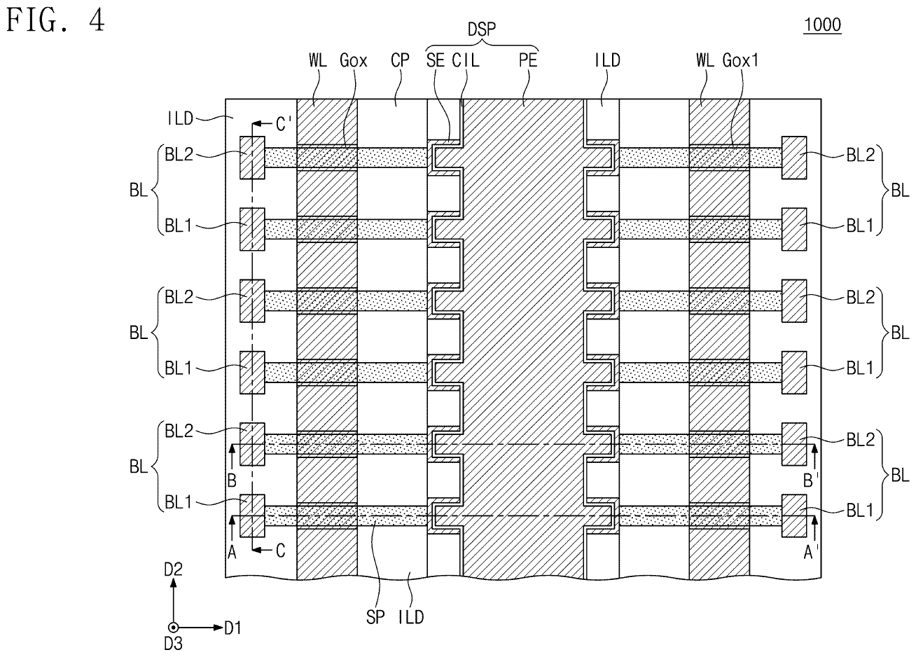

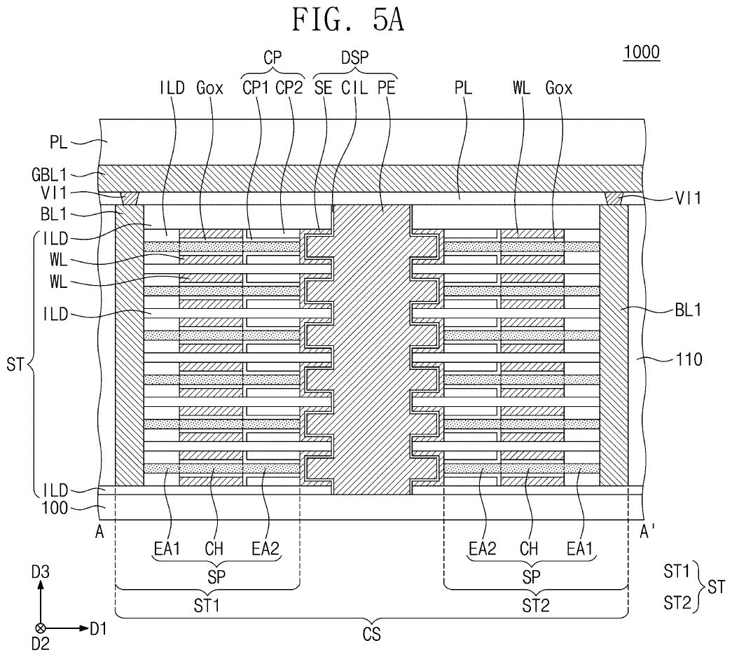

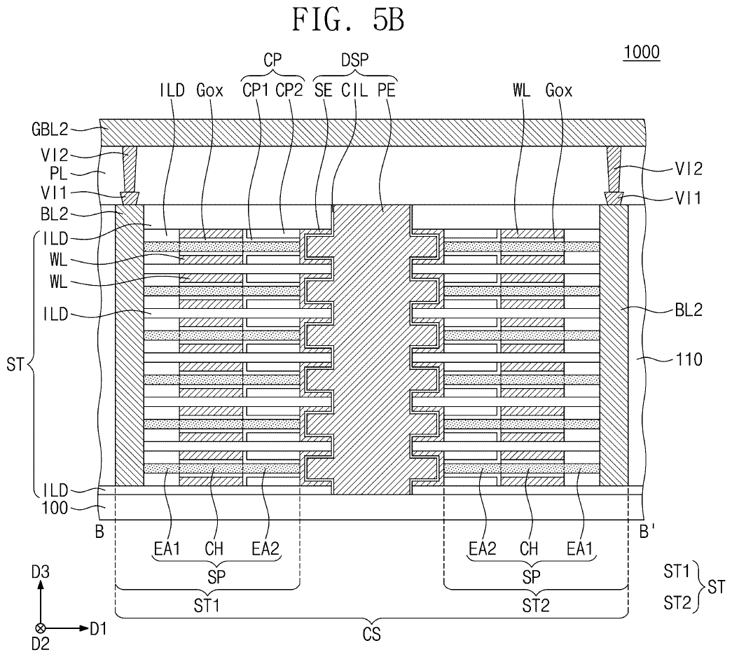

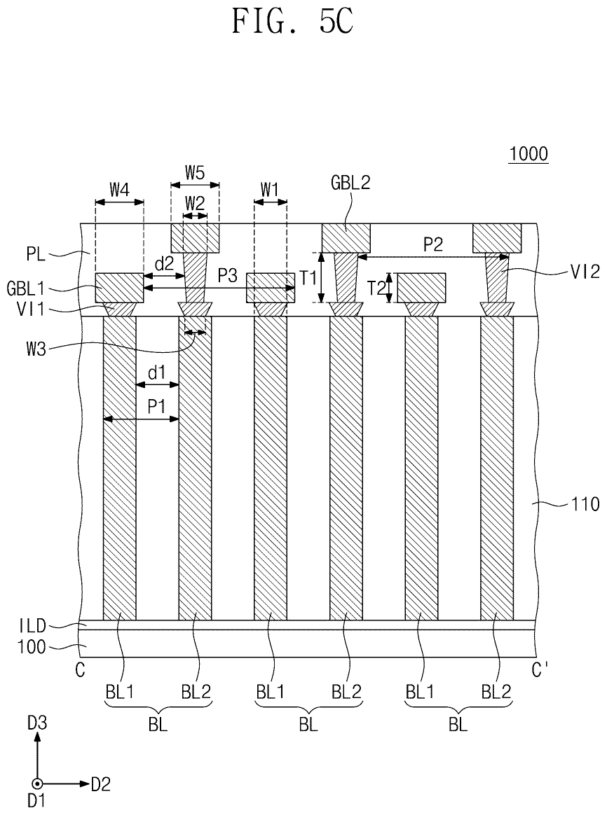

FIG. 3 is a perspective view illustrating semiconductor patterns, word lines, bit lines, global bit lines, and data storage pattern of a three-dimensional semiconductor device according to some embodiments of the inventive concept. FIG. 4 is a plan view illustrating a three-dimensional semiconductor device according to some embodiments of the inventive concept. FIG. 5A is a sectional view taken along a line A-A′ of FIG. 4. FIG. 5B is a sectional view taken along a line B-B′ of FIG. 4. FIG. 5C is a sectional view taken along a line C-C′ of FIG. 4.

Referring to FIGS. 3, 4, 5A, 5B, and 5C, a three-dimensional semiconductor device 1000 may include the substrate 100. In some embodiments, the substrate 100 may be a semiconductor substrate, an insulating substrate, a silicon-on-insulator (SOI) substrate, or a germanium-on-insulator (GOI) substrate. The semiconductor substrate may be, for example, a silicon substrate, a germanium substrate, or a silicon-germanium substrate. The substrate 100 may be a plate-shaped structure that is extended parallel to a plane defined by the first and second directions D1 and D2. In the present specification, the first and second directions D1 and D2 may be parallel to the bottom surface of the substrate 100 and may not be parallel to each other. A third direction D3 may be the vertical direction D3 perpendicular to the bottom surface of the substrate 100. In some embodiments, the first to third directions D1, D2, and D3 may be orthogonal to each other.

The cell array structure CS may be provided on the substrate 100. The cell array structure CS may include a plurality of stacks ST and a data storage pattern DSP therebetween. In detail, the cell array structure CS may include a first stack ST1 and a second stack ST2, which are spaced apart from each other in the first direction D1, and the data storage pattern DSP therebetween. In some embodiments, although not shown, a plurality of cell array structures CS may be provided. The cell array structures CS may be spaced apart from each other in the first direction D1. Hereinafter, just one cell array structure CS will be described, for brevity's sake, but the others of the cell array structures CS may also have substantially the same features as described below.

Each of the first and second stacks ST1 and ST2 may include semiconductor patterns SP, word lines WL, bit lines BL, gate insulating layers Gox, first capping patterns CP1, second capping patterns CP2, and an insulating pattern ILD. In some embodiments, the first and second stacks ST1 and ST2 may be provided to have a mirror symmetry with respect to the data storage pattern DSP.

The semiconductor pattern SP may be extended in the first direction D1, on the substrate 100. In some embodiments, the semiconductor pattern SP may be a bar-shaped pattern, which is extended in the first direction D1. The semiconductor pattern SP may be spaced apart from the substrate 100. That is, the semiconductor pattern SP may be floated from the substrate 100.

The semiconductor pattern SP may include a first edge portion EA1 and a second edge portion EA2, which are spaced apart from each other in the first direction D1, and a channel region CH therebetween. The channel region CH of the semiconductor pattern SP may be enclosed or at least partially enclosed by the word line WL. The first edge portion EA1 of the semiconductor pattern SP may be adjacent to the bit line BL. The first edge portion EA1 may be in contact with and electrically connected to the bit line BL. The second edge portion EA2 may be adjacent to the data storage pattern DSP. The second edge portion EA2 may be in contact with and electrically connected to the data storage pattern DSP.

The semiconductor pattern SP may have a first side surface and a second side surface in the first direction D1, which are opposite to each other. The first side surface may be a side surface of the first edge portion EA1, and the second side surface may be a side surface of the second edge portion EA2. The first side surface of the semiconductor pattern SP may be in contact with the bit line BL, and the second side surface may be in contact with the data storage pattern DSP.

The semiconductor pattern SP may be formed of or include at least one of single-crystalline semiconductor materials, polycrystalline semiconductor materials, oxide semiconductor materials, and/or two-dimensional materials. In some embodiments, the single-crystalline semiconductor material may be single-crystalline silicon. In some embodiments, the polycrystalline semiconductor material may be polysilicon. In some embodiments, the oxide semiconductor material may be Indium Gallium Zinc Oxide (IGZO). In some embodiments, the two-dimensional material may be MoS₂, WS₂, MoSe₂, or WSe₂.

In some embodiments, each of the first and second edge portions EA1 and EA2 of the semiconductor pattern SP may include an impurity region that is doped with impurities (e.g., n- or p-type impurities). The impurity region may constitute or include a source/drain region of a transistor.

In some embodiments, a plurality of semiconductor patterns SP may be provided. The semiconductor patterns SP may be adjacent to each other in the second and third directions D2 and D3. The semiconductor patterns SP, which are adjacent to each other in the third direction D3, may be vertically overlapped with each other. The semiconductor patterns SP, which are adjacent to each other in the third direction D3, may have side surfaces that are aligned to each other.

The semiconductor pattern SP may be provided in the first stack ST1 and may be provided in the second stack ST2. The semiconductor pattern SP in the first stack ST1 may be adjacent to the semiconductor pattern SP in the second stack ST2 in the first direction D1. The first and second edge portions EA1 and EA2 of the semiconductor pattern SP in the first stack ST1 may be sequentially disposed in the first direction D1. The first and second edge portions EA1 and EA2 of the semiconductor pattern SP in the second stack ST2 may be sequentially disposed in a direction opposite to the first direction D1.

The word line WL may be provided to enclose or at least partially enclose the channel region CH of the semiconductor pattern SP and may be extended in the second direction D2. In some embodiments, the word line WL may be provided to fully surround the channel region CH of the semiconductor pattern SP and may have a structure (i.e., a gate-all-around structure). Each of the word lines WL may be provided to surround the channel region CH of each of the semiconductor patterns SP, which are adjacent to each other in the second direction D2. In some embodiments, a plurality of word lines WL may be provided. Each of the word lines WL may be provided to surround the channel region CH of one of the semiconductor patterns SP, which are adjacent to each other in the third direction D3 and may be extended in the second direction D2.

The word line WL may enclose the channel region CH of the semiconductor pattern SP in the first stack ST1. The word line WL may enclose the channel region CH of the semiconductor pattern SP in the second stack ST2.

The word line WL may be formed of or include at least one of doped polysilicon, metallic materials (e.g., Al, Cu, Ti, Ta, Ru, W, Mo, Pt, Ni, and/or Co), conductive metal nitride materials (e.g., TiN, TaN, WN, NbN, TiAlN, TiSiN, TaSiN, and/or RuTiN), conductive metal silicide materials, or conductive metal oxide materials (e.g., PtO, RuO₂, IrO₂, SrRuO₃ (SRO), (Ba,Sr)RuO₃ (BSRO), CaRuO₃ (CRO), and/or LSCo), but the inventive concept is not limited to this example. The word line WL may be provided to have a single- or multi-layered structure formed of the afore-described materials. In some embodiments, the word line WL may be formed of or include at least one of two-dimensional semiconductor materials (e.g., graphene, carbon nanotube, or combinations thereof).

Although not shown, word line pads (not shown) may be provided on a side surface of the cell array structure CS and may be electrically connected to the word lines WL.

The gate insulating layer Gox may be interposed between the word line WL and the semiconductor pattern SP, in the first stack ST1 and/or the second stack ST2. The gate insulating layer Gox may enclose the word line WL. The word line WL may be provided to enclose the channel region CH of the semiconductor pattern SP, on the gate insulating layer Gox. In some embodiments, a plurality of gate insulating layers Gox may be provided. Each of the gate insulating layers Gox may enclose a corresponding one of the semiconductor patterns SP.

The gate insulating layer Gox may be formed of or include at least one of silicon oxide, silicon oxynitride, or high-k dielectric materials having dielectric constants higher than silicon oxide. The high-k dielectric material may include metal oxide materials or metal oxynitride materials. For example, the high-k dielectric material for the gate insulating layer Gox may include at least one of HfO₂, HfSiO, HfSiON, HfTaO, HfTiO, HfZrO, ZrO₂, or Al₂O₃, but the inventive concept is not limited to this example. The high-k dielectric material may be defined as a material having a dielectric constant higher than silicon oxide.

The bit line BL may be provided on the first side surface of the semiconductor pattern SP (i.e., the side surface of the first edge portion EA1). The bit line BL may be extended in the third direction D3, on the first side surface of the semiconductor pattern SP. Thus, each of the bit lines BL may be in contact with and electrically connected to the first side surface of each of the semiconductor patterns SP, which are adjacent to each other in the third direction D3. In some embodiments, a plurality of bit lines BL may be provided. The bit lines BL may be adjacent to each other in the second direction D2.

The bit line BL may include a first bit line BL1 and a second bit line BL2. The first bit line BL1 may be connected to a first global bit line GBL1, which will be described below. The second bit line BL2 may be connected to a second global bit line GBL2, which will be described below. The first and second bit lines BL1 and BL2 may be alternately disposed in the second direction D2.

The bit line BL may be a single layer, which is made of a single material, or a composite layer including two or more materials. In some embodiments, the bit line BL may be formed of or include at least one of metallic materials (e.g., Ti, Mo, W, Cu, Al, Ta, Ru, Ir, and/or Co), metal nitride materials (e.g., nitride materials containing Ti, Mo, W, Cu, Al, Ta, Ru, Ir, and/or Co), or metal silicide materials (e.g., silicide materials containing Ti, Mo, W, Cu, Al, Ta, Ru, Ir, and/or Co).

The data storage pattern DSP may be interposed between the first and second stacks ST1 and ST2. The data storage pattern DSP may be interposed between the first semiconductor pattern SP and the second semiconductor pattern SP. The data storage pattern DSP may be in contact with a second side surface of the first semiconductor pattern SP (i.e., the side surface of the second edge portion EA2) and may be electrically connected to the first semiconductor pattern SP. The data storage pattern DSP may be in contact with a second side surface of the second semiconductor pattern SP and may be electrically connected to the second semiconductor pattern SP.

The data storage pattern DSP may include a storage electrode SE, a plate electrode PE, and a capacitor dielectric layer CIL therebetween. In some embodiments, the three-dimensional semiconductor device may be a dynamic random access memory (DRAM) device, and here, the data storage pattern DSP may be used as a capacitor. The storage electrode SE may be spaced apart from the plate electrode PE by the capacitor dielectric layer CIL.

Each of the storage and plate electrodes SE and PE may include a conductive material. In some embodiments, each of the storage and plate electrodes SE and PE may be formed of or include at least one of doped silicon (Si), doped silicon germanium (SiGe), metallic materials (e.g., Ti, Mo, W, Cu, Al, Ta, Ru, Ir, Co, Pt, Au, and/or Ag), metal nitride materials (e.g., nitride materials containing Ti, Mo, W, Cu, Al, Ta, Ru, Ir, Co, Pt, Au, and/or Ag), titanium silicon nitride (e.g., TiSiN), titanium aluminum nitride (e.g., TiAlN), tantalum aluminum nitride (e.g., TaAlN), conductive oxide materials (e.g., PtO, RuO₂, IrO₂, SrRuO₃ (SRO), (Ba,Sr)RuO₃ (BSRO), CaRuO₃ (CRO), and/or LSCo), or metal silicide materials. Each of the storage and plate electrodes SE and PE may be a single layer, which is made of a single material, or a composite layer including two or more materials.

In some embodiments, the capacitor dielectric layer CIL may include at least one of metal oxide materials (e.g., HfO₂, ZrO₂, Al₂O₃, La₂O₃, Ta₂O₃, and/or TiO₂) and perovskite dielectric materials (e.g., SrTiO₃ (STO), (Ba,Sr) TiO₃ (BST), BaTiO₃, PZT, and/or PLZT).

In some embodiments, the data storage pattern DSP may be a variable resistance pattern whose resistance can be switched to one of at least two states by an electric pulse applied thereto. For example, the data storage pattern DSP may be formed of or include at least one of phase-change materials whose crystal state can be changed depending on an amount of a current applied thereto, perovskite compounds, transition metal oxides, magnetic materials, ferromagnetic materials, or antiferromagnetic materials.

The storage electrode SE may be extended from a second side surface of a first semiconductor pattern SPa in the first direction D1. The storage electrode SE may be extended from a second side surface of a second semiconductor pattern SPb in a direction opposite to the first direction D1. Although not shown, a silicide pattern (not shown) may be provided between the storage electrode SE and the first semiconductor pattern SPa and between the storage electrode SE and the second semiconductor pattern SPb. The silicide pattern may be formed of or include at least one of metal silicide materials (e.g., containing Ti, Mo, W, Cu, Al, Ta, Ru, Ir, and/or Co). In some embodiments, a plurality of storage electrodes SE may be provided, and the storage electrodes SE may be adjacent to each other in the third direction D3.

The plate electrode PE may include a vertical portion, which is extended in the third direction D3, and horizontal portion, which is extended from the vertical portion in the first direction D1 or an opposite direction of the first direction D1. The horizontal portions of the plate electrode PE may be interposed between the storage electrodes SE, which are adjacent to each other in the third direction D3.

The insulating pattern ILD may be provided on the substrate 100. The insulating pattern ILD may cover, overlap, or be on the side surface of the cell array structure CS. The insulating pattern ILD may be interposed between the bit line BL and the word line WL, between the semiconductor patterns SP, which are adjacent to each other in the third direction D3, between the first edge portions EA1 of the semiconductor patterns SP, which are adjacent to each other in the second direction D2, and between the word lines WL, which are adjacent to each other in the third direction D3. The insulating pattern ILD may include a single or composite layer including an insulating material.

A capping pattern CP may be provided in the cell array structure CS. The capping pattern CP may be interposed between the word lines WL and the data storage pattern DSP. The capping pattern CP may be interposed between the semiconductor patterns SP, which are adjacent to each other in the third direction D3. The capping pattern CP may be interposed between the second edge portions EA2 of the semiconductor patterns SP, which are adjacent to each other in the second direction D2.

The capping pattern CP may include the first capping pattern CP1 enclosing the second edge portion EA2 of the semiconductor pattern SP and the second capping pattern CP2 on the first capping pattern CP1. The first capping pattern CP1 may conformally cover or overlap the second edge portion EA2 of the semiconductor pattern SP and a side surface of the word line WL. Each of the first and second capping patterns CP1 and CP2 may include an insulating material. The second capping pattern CP2 may include a single layer or a composite layer.

A global bit line GBL may be provided on the bit line BL. The global bit line GBL may be a higher-level bit line, which collectively processes data from the bit line BL of the 3D device.

The global bit line GBL may be extended in the first direction D1. In some embodiments, a plurality of global bit lines GBL may be provided. The global bit lines GBL may be spaced apart from each other in the second direction D2 and may be alternately disposed in the second direction D2. The global bit line GBL may include the first global bit line GBL1 and the second global bit line GBL2. Due to a difference in level between the top surfaces of the first and second global bit lines GBL1 and GBL2 to be described below, two adjacent ones of the global bit lines GBL may have top surfaces located at different levels. As used herein, a “level” may refer to a distance in a specific direction from an element, such as, for example, a distance in the third direction D3 from the substrate 100.

In detail, the first global bit line GBL1 may be provided on the first bit line BL1, and the second global bit line GBL2 may be provided on the second bit line BL2. The first global bit line GBL1 may connect the first bit lines BL1 of the first and second stacks ST1 and ST2, which are spaced apart from each other in the first direction D1, to each other. The second global bit line GBL2 may connect the second bit lines BL2 of the first and second stacks ST1 and ST2, which are spaced apart from each other in the first direction D1, to each other.

A level of the top surface of the first global bit line GBL1 may be different from a level of the top surface of the second global bit line GBL2. A level of a bottom surface of the second global bit line GBL2 may be equal to or higher than the level of the top surface of the first global bit line GBL1. In some embodiments, a first via VI1 may be interposed between the first bit line BL1 and the first global bit line GBL1, and the first via VI1 and a second via VI2 may be interposed between the second bit line BL2 and the second global bit line GBL2. The second via VI2 may be interposed between the first via VI1 and the second global bit line GBL2.

The second via VI2 may be provided at the same level as the first global bit line GBL1. A level of a top surface of the second via VI2 may be higher than the level of the top surface of the first global bit line GBL1. The second via VI2 may be overlapped with the second bit line BL2 and/or the second global bit line GBL2 in the third direction D3.

The first and second global bit lines GBL1 and GBL2 may be disposed in a direction between the second and third directions D2 and D3 or in a zigzag shape. That is, the rows and columns of the first and second global bit lines GBL1 and GBL2 may be offset from each other in a cross-sectional view.

Referring to FIG. 5C, the bit line BL may have a first width W1 in the second direction D2. The bit lines BL may be disposed to have a first pitch P1 in the second direction D2 and may be spaced apart from each other by a first distance d1 in the second direction D2. The top surface of the second via VI2 may have a second width W2 in the second direction D2, and a bottom surface of the second via VI2 may have a third width W3 in the second direction D2. The second via VI2 may have a first thickness T1 in the third direction D3. The second vias VI2 may be disposed to have a second pitch P2 in the second direction D2. The first global bit line GBL1 may have a fourth width W4 in the second direction D2 and may have a second thickness T2 in the third direction D3. The first global bit lines GBL1 may be provided to have a third pitch P3 in the second direction D2. The second via VI2 and the first global bit line GBL1 may be spaced apart from each other by a second distance d2 in the second direction D2. The second global bit line GBL2 may have a fifth width W5 in the second direction D2.

The fourth width W4 of the first global bit line GBL1 may be equal to or larger than the first width W1 of the bit line BL. The fifth width W5 of the second global bit line GBL2 may be equal to or larger than the first width W1 of the bit line BL.

The third width W3 of the bottom surface of the second via VI2 may be equal to or smaller than the fifth width W5 of the second global bit line GBL2. The third width W3 of the bottom surface of the second via VI2 may be equal to or smaller than the fourth width W4 of the first global bit line GBL1. The second width W2 of the top surface of the second via VI2 may be equal to or smaller than the fifth width W5 of the second global bit line GBL2. The second width W2 of the top surface of the second via VI2 may be equal to or smaller than the fourth width W4 of the first global bit line GBL1. In some embodiments, a width of the second via VI2 (for example, the second width W2) may be equal to or smaller than a width of the global bit line GBL (for example, the fourth width W4).

The first pitch P1 between the bit lines BL may be smaller than the third pitch P3 between the first global bit lines GBL1. In some embodiments, the first distance d1 between the bit lines BL may be equal to or smaller than the second distance d2 between the first global bit line GBL1 and the second via VI2.

The first thickness T1 of the second via VI2 may be equal to or larger than the second thickness T2 of the first global bit line GBL1.

A protection layer PL may be provided on the first stack ST1 and/or the second stack ST2. The protection layer PL may cover, overlap, or be on the top surfaces of the first stack ST1, the second stack ST2, and the data storage pattern DSP. The protection layer PL may include a single or composite layer including an insulating material.

The protection layer PL may cover, overlap, or be on side and bottom surfaces of the global bit line GBL and side surfaces of the first and second vias VI1 and VI2.

In the three-dimensional semiconductor device according to some embodiments of the inventive concept, adjacent ones of the global bit lines GBL may be placed at different levels, and in this case, it may be possible to increase a distance between the global bit lines GBL. For example, in FIG. 5C, the first global bit lines GBL1 are at different levels than the second global bit lines GBL2. Accordingly, it may be possible to reduce the capacitance of the bit line and increase the number of the stacks. As a result, the semiconductor device with improved reliability may be provided.

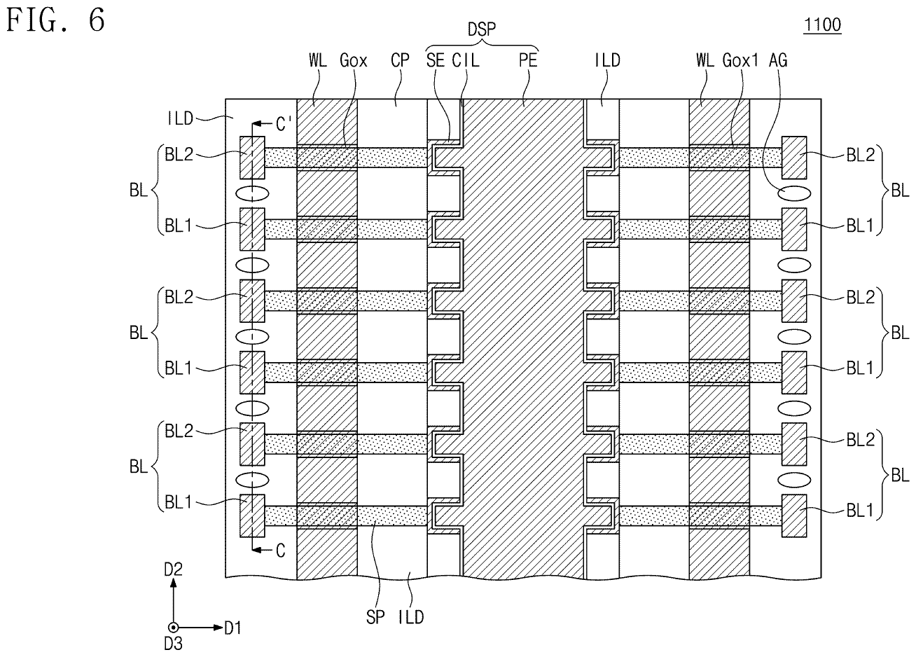

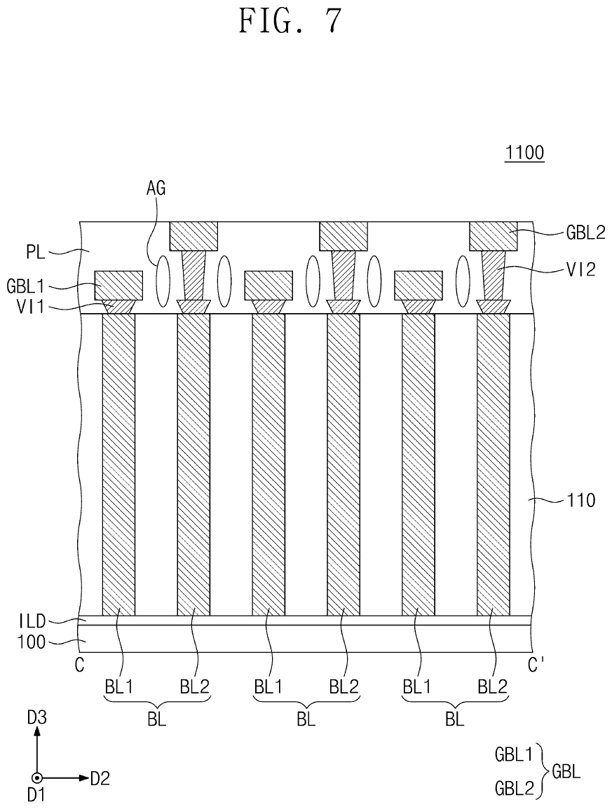

FIG. 6 is a plan view illustrating a three-dimensional semiconductor device according to some embodiments of the inventive concept. FIG. 7 is a sectional view taken along a line C-C′ of FIG. 6. For concise description, an element described with reference to FIGS. 3 to 5C may be identified by the same reference number without repeating an overlapping description thereof.

Referring to FIGS. 6 and 7, a three-dimensional semiconductor device 1100 may further include an air gap AG. In some embodiments, a plurality of air gaps AG may be provided. The air gap AG may be interposed between the first global bit line GBL1 and the second via VI2.

According to some embodiments of the inventive concept, the air gap AG may be provided between the first global bit line GBL1 and the second via VI2 to enhance insulating characteristics of the three-dimensional semiconductor device. In this case, it may be possible to reduce the capacitance of the bit line and increase the number of the stacks. As a result, the semiconductor device with improved reliability may be provided.

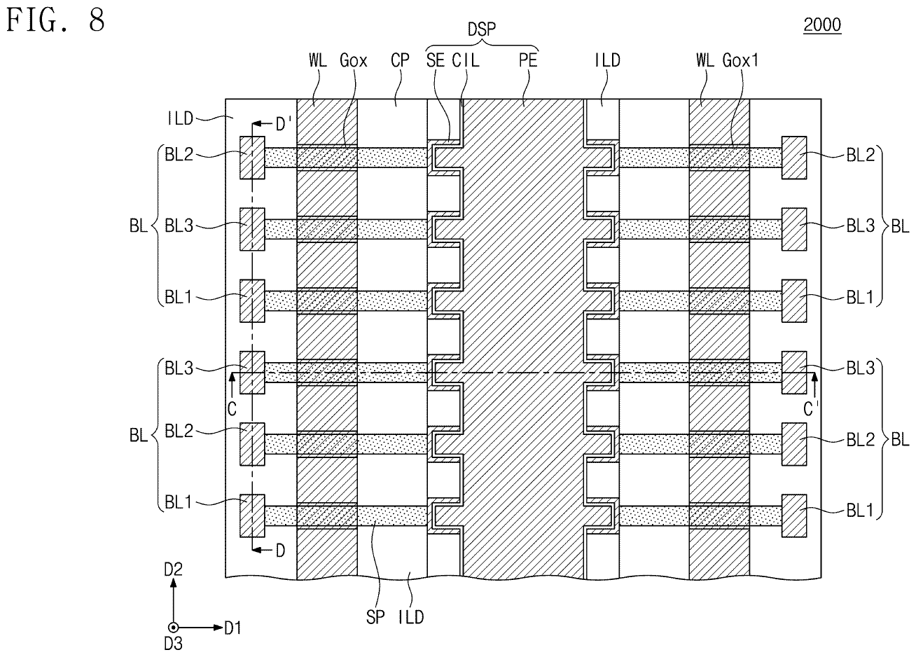

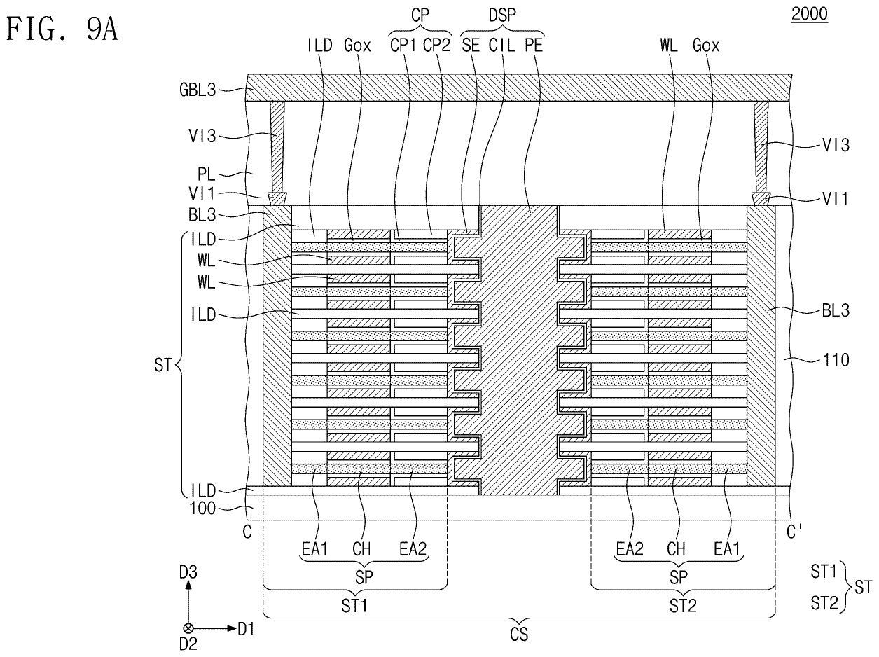

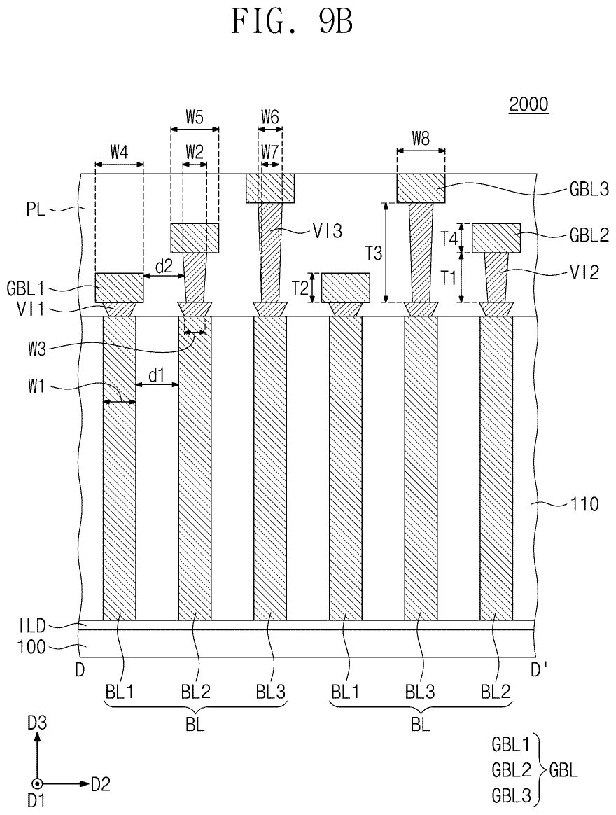

FIG. 8 is a plan view illustrating a three-dimensional semiconductor device according to some embodiments of the inventive concept. FIG. 9A is a sectional view taken along a line C-C′ of FIG. 8. FIG. 9B is a sectional view taken along a line D-D′ of FIG. 8. For concise description, an element described with reference to FIGS. 3 to 5C may be identified by the same reference number without repeating an overlapping description thereof.

Referring to FIGS. 8, 9A, and 9B, the bit line BL of a three-dimensional semiconductor device 2000 may further include a third bit line BL3, and the global bit line GBL of the three-dimensional semiconductor device 2000 may further include a third global bit line GBL3. The third bit line BL3 and the third global bit line GBL3 may be connected to each other, and the third global bit line GBL3 may be provided on the third bit line BL3.

The third global bit line GBL3 may be provided to connect the third bit lines BL3 of the first and second stacks ST1 and ST2, which are spaced apart from each other in the first direction D1, to each other. A level of a top surface of the third global bit line GBL3 may be different from the level of the top surface of the first global bit line GBL1 and the level of the top surface of the second global bit line GBL2. In detail, the level of the bottom surface of the third global bit line GBL3 may be equal to or higher than the level of the top surface of the second global bit line GBL2. The first via VI1 and a third via VI3 may be interposed between the third bit line BL3 and the third global bit line GBL3. The third via VI3 may be interposed between the first via VI1 and the third global bit line GBL3.

The third via VI3 may be placed at the same level as the second global bit line GBL2. A level of a top surface of the third via VI3 may be higher than a level of the top surface of the second global bit line GBL2. The third via VI3 may be overlapped with the third bit line BL3 and/or the third global bit line GBL3 in the third direction D3.

In the three-dimensional semiconductor device 2000, two global bit lines GBL, which are adjacent to each other in the second direction D2, may also be placed at different levels. The inventive concept is not limited to the disposition of the bit line BL or the global bit line GBL, but the global bit lines GBL placed at different levels may be adjacent to each other in the second direction D2. In this case, the bit lines BL connected to the global bit lines GBL may be adjacent to each other in the second direction D2.

In some embodiments, the first and second bit lines BL1 and BL2 may be adjacent to each other in the second direction D2, the first and third bit lines BL1 and BL3 may be adjacent to each other in the second direction D2, and the second and third bit lines BL2 and BL3 may be adjacent to each other in the second direction D2. In some embodiments, the first and second global bit lines GBL1 and GBL2 may be adjacent to each other in the second direction D2, the first and third global bit lines GBL1 and GBL3 may be adjacent to each other in the second direction D2, and the second and third global bit lines GBL2 and GBL3 may be adjacent to each other in the second direction D2.

Referring to FIG. 9B, the third via VI3 may have a third thickness T3 in the third direction D3. The top surface of the third via VI3 may have a sixth width W6 in the second direction D2, and a bottom surface of the third via VI3 may have a seventh width W7 in the second direction D2. The second global bit line GBL2 may have a fourth thickness T4 in the third direction D3. The third global bit line GBL3 may have an eighth width W8 in the second direction D2.

The eighth width W8 of the third global bit line GBL3 may be equal to or larger than the first width W1 of the bit line BL.

The seventh width W7 of the bottom surface of the third via VI3 may be equal to or smaller than the eighth width W8 of the third global bit line GBL3. The seventh width W7 of the bottom surface of the third via VI3 may be equal to or smaller than the fifth width W5 of the second global bit line GBL2. The sixth width W6 of the top surface of the third via VI3 may be equal to or smaller than the eighth width W8 of the third global bit line GBL3. The sixth width W6 of the top surface of the third via VI3 may be equal to or smaller than the fifth width W5 of the second global bit line GBL2. In some embodiments, a width of the third via VI3 (for example, the sixth width W6) may be equal to or smaller than a width of the global bit line GBL (for example, the fourth width W4).

The third thickness T3 of the third via VI3 may be larger than the first thickness T1 of the second via VI2. In detail, the third thickness T3 of the third via VI3 may be equal to or larger than a sum of the first thickness T1 of the second via VI2 and the fourth thickness T4 of the second global bit line GBL2.

In the three-dimensional semiconductor device according to some embodiments of the inventive concept, adjacent ones of the global bit lines GBL may be placed at three or more levels, and in this case, it may be possible to further increase the distances between the global bit lines GBL. Accordingly, it may be possible to reduce the capacitance of the bit line and increase the number of the stacks. As a result, the semiconductor device with improved reliability may be provided.

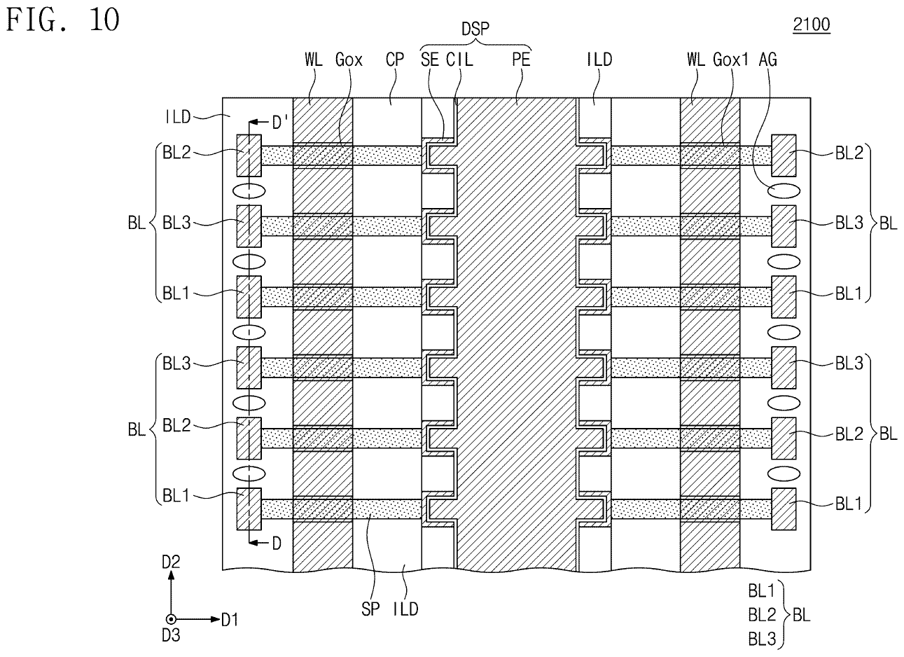

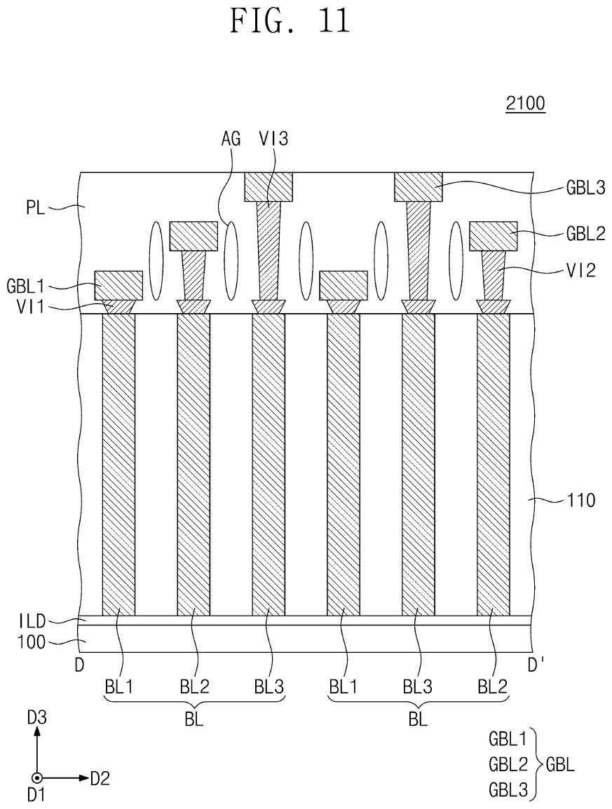

FIG. 10 is a plan view illustrating a three-dimensional semiconductor device according to some embodiments of the inventive concept. FIG. 11 is a sectional view taken along a line D-D′ of FIG. 10. For concise description, an element described with reference to FIGS. 8 to 9D may be identified by the same reference number without repeating an overlapping description thereof.

Referring to FIGS. 10 and 11, a three-dimensional semiconductor device 2100 may further include the air gap AG. In some embodiments, a plurality of air gaps AG may be provided. The air gap AG may be interposed between the first global bit line GBL1 and the second via VI2, between the first global bit line GBL1 and the third via VI3, and/or between the second global bit line GBL2 and the third via VI3.

In some embodiments, the air gap AG may be provided to enhance insulating characteristics of the three-dimensional semiconductor device. In this case, it may be possible to reduce the capacitance of the bit line and increase the number of the stacks. As a result, the semiconductor device with improved reliability may be provided.

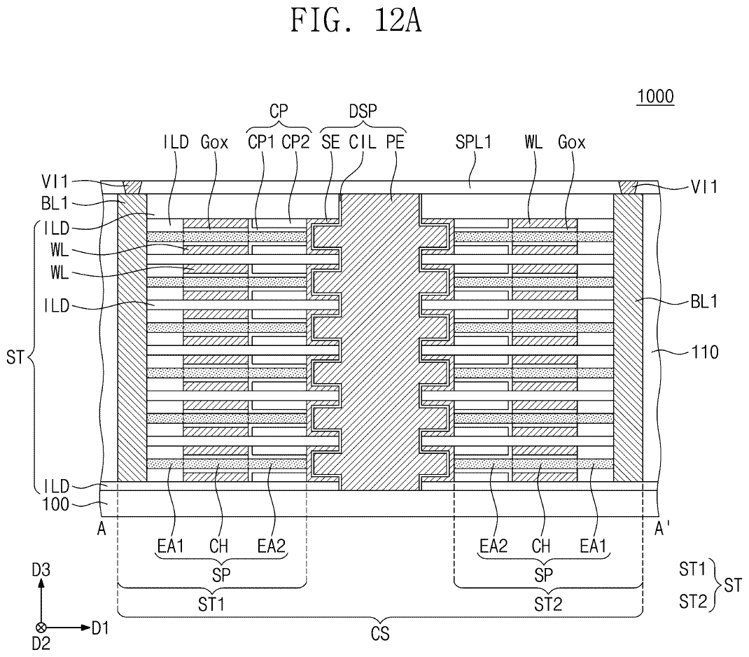

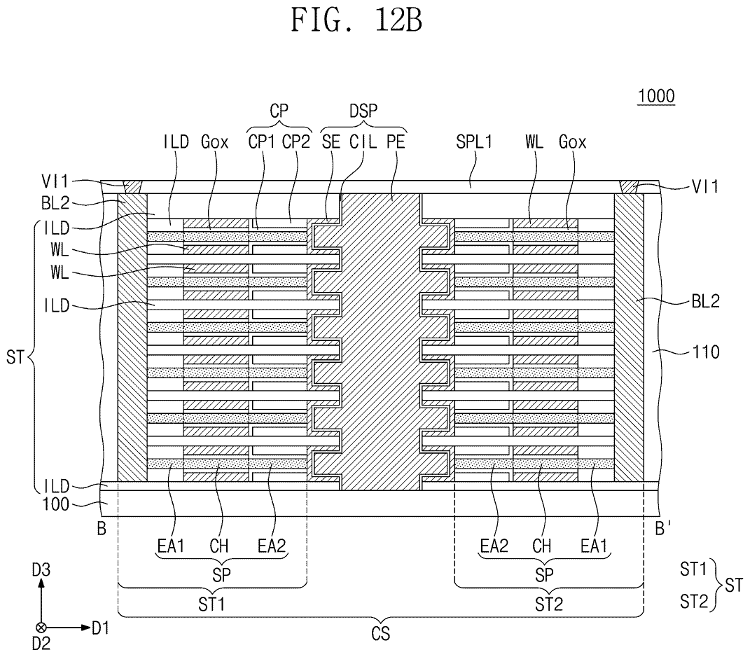

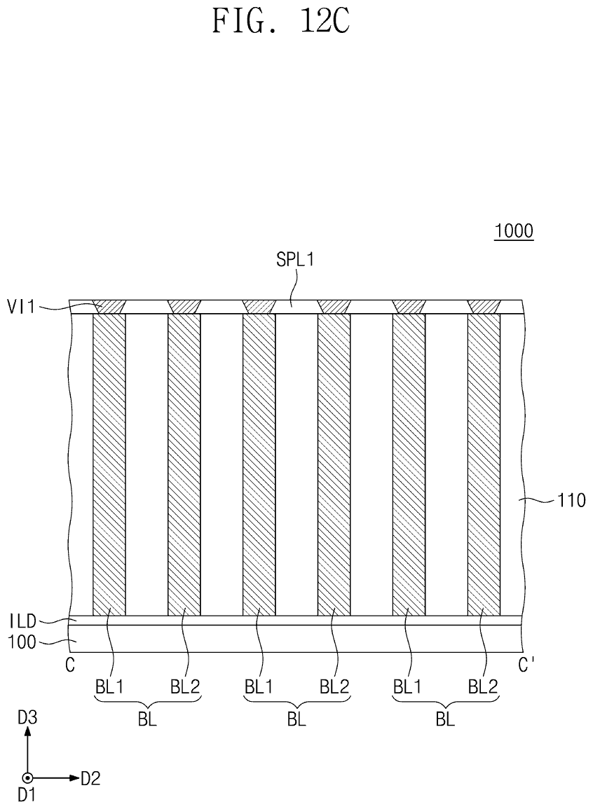

FIGS. 12A, 12B, 12C, 13A, 13B, 13C, 14A, 14B, and 14C are diagrams illustrating a method of fabricating a three-dimensional semiconductor device, according to some embodiments of the inventive concept. FIGS. 12A, 13A, and 14A are sectional views corresponding to the line A-A′ of FIG. 4. FIGS. 12B, 13B, and 14B are sectional views corresponding to the line B-B′ of FIG. 4. FIGS. 12C, 13C, and 14C are sectional views corresponding to the line C-C′ of FIG. 4.

Referring to FIGS. 12A, 12B, and 12C, the first and second stacks ST1 and ST2 may be formed on the substrate 100. The first via VI1 may be formed on the bit line BL of the first stack ST1 and the bit line BL of the second stack ST2.

The formation of the first via VI1 may include forming a first insulating layer SPL1 on the first and second stacks ST1 and ST2, patterning the first insulating layer SPL1 to form an opening exposing top surfaces of the first and second bit lines BL1 and BL2, and filling the opening with a metallic material.

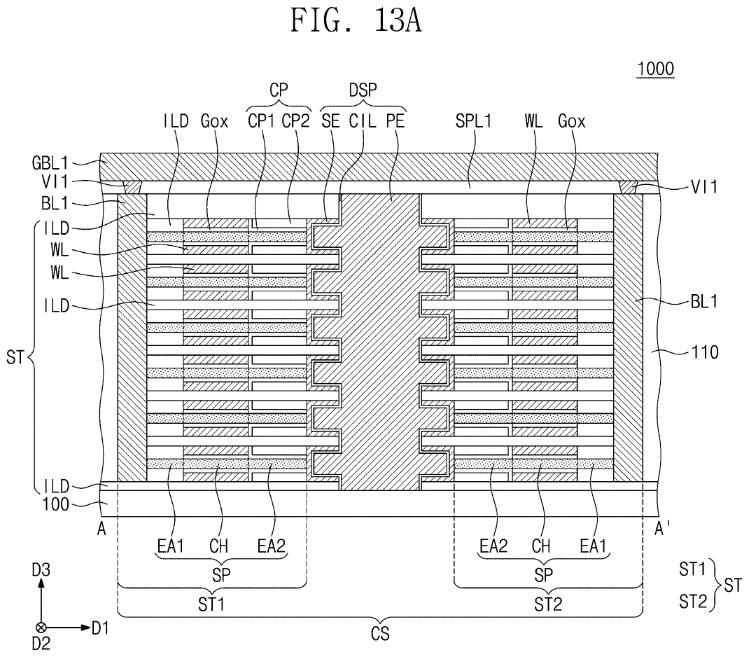

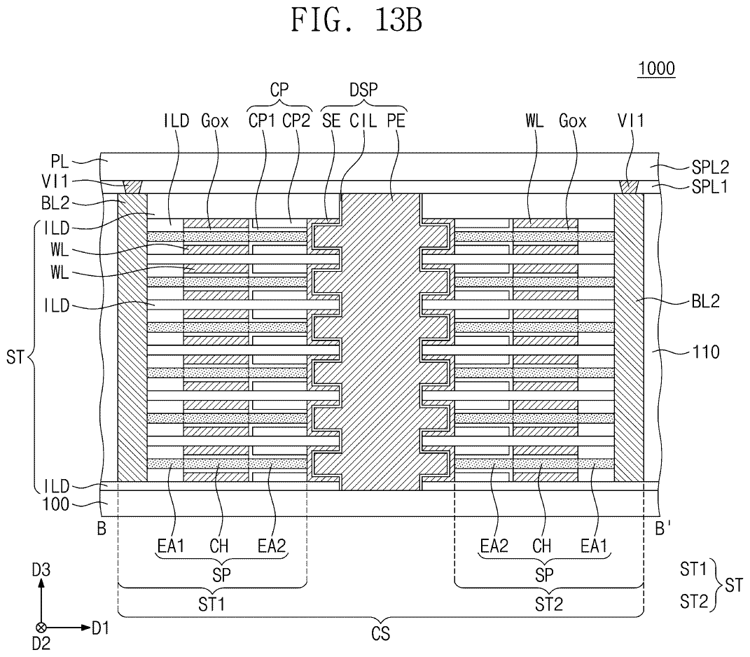

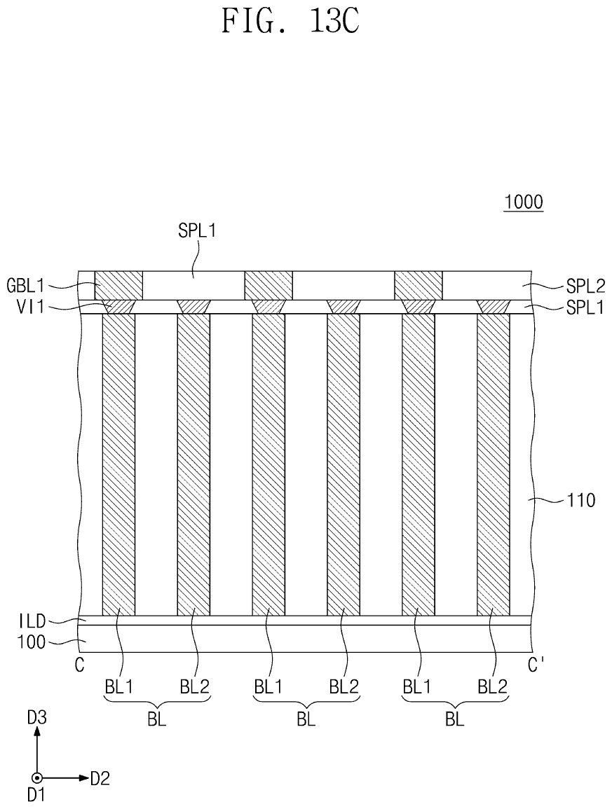

Referring to FIGS. 13A, 13B, and 13C, the first global bit line GBL1 may be formed on the first via VI1. The formation of the first global bit line GBL1 may include forming a first global bit line layer (not shown) on the first insulating layer SPL1, patterning the first global bit line layer (not shown), and forming a second insulating layer SPL2 on the first via VI1 on the second bit line BL2.

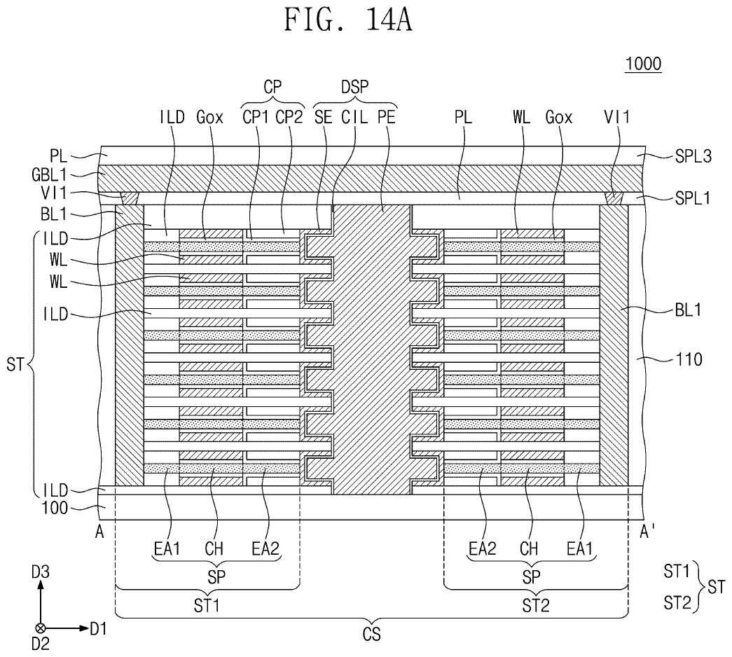

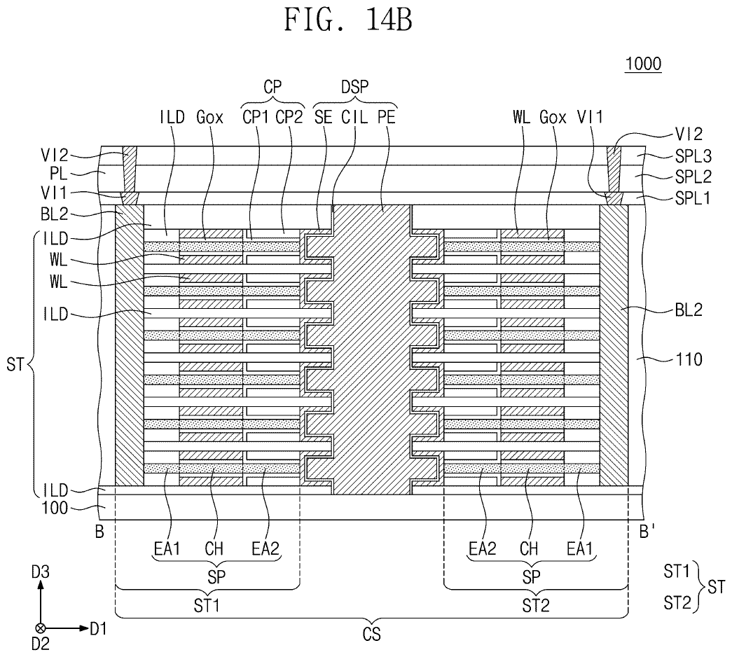

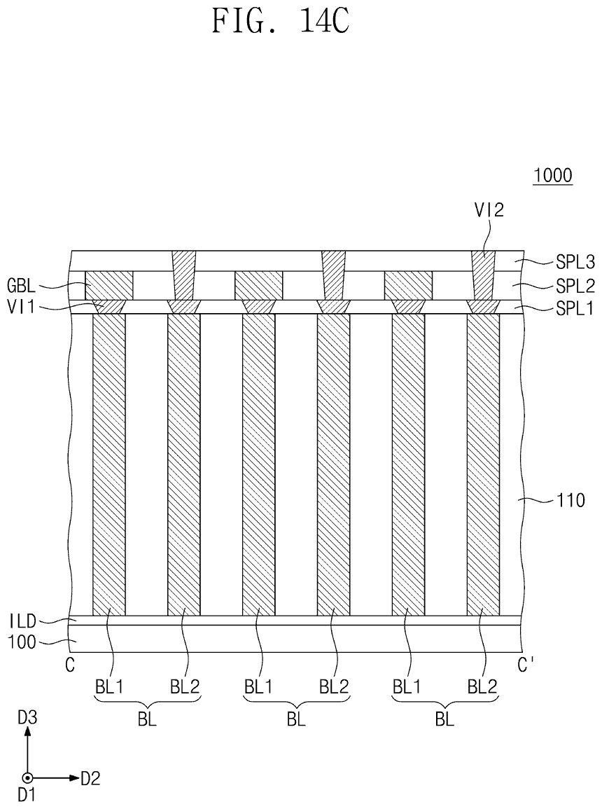

Referring to FIGS. 14A, 14B, and 14C, the second via VI2 may be formed on the first via VI1 on the second bit line BL2. The formation of the second via VI2 may include forming a third insulating layer SPL3 on the first global bit line GBL1 and the second insulating layer SPL2, patterning the third insulating layer SPL3 to form an opening exposing a top surface of the first via VI1, and filling the opening with a metallic material.

Referring back to FIGS. 5A, 5B, and 5C, the second global bit line GBL2 may be formed on the second via VI2. The formation of the second global bit line GBL2 may include forming a second global bit line layer (not shown) on a third protection layer material PL and the second via VI2, patterning the second global bit line layer (not shown), and forming a fourth insulating layer (not shown) on the third insulating layer SPL3 to form the protection layer PL.

According to some embodiments of the inventive concept, a semiconductor device may include global bit lines, which have top surfaces placed at different levels. In this case, it may be possible to increase the number of the stacks and to improve the capacitance of the bit line. As a result, the semiconductor device with improved reliability may be provided.

While example embodiments of the inventive concept have been particularly shown and described, it will be understood by one of ordinary skill in the art that variations in form and detail may be made therein without departing from the scope of the attached claims.

What is claimed is:

1. A three-dimensional (3D) semiconductor device, comprising:
a substrate;
bit lines on the substrate, extending in a first direction perpendicular to a bottom surface of the substrate, and comprising a first bit line and a second bit line, which are spaced apart from and adjacent to each other in a second direction parallel to the bottom surface of the substrate,
semiconductor patterns on the bit lines and extending in a third direction perpendicular to the first and second directions;
word lines enclosing a portion of the semiconductor patterns and extending in the second direction;
a first global bit line on the first bit line and extending in the third direction;
a second global bit line on the second bit line and extending in the third direction; and
a first via on a top surface of the second bit line and between the second bit line and the second global bit line,
wherein a distance from the bottom surface of the substrate in the first direction to a top surface of the first global bit line is different from a distance from the bottom surface of the substrate in the first direction to a top surface of the second global bit line.

2. The 3D semiconductor device of claim 1, wherein a distance from the bottom surface of the substrate in the first direction to a bottom surface of the second global bit line is equal to or greater than the distance from the bottom surface of the substrate in the first direction of the top surface of the first global bit line.

3. The 3D semiconductor device of claim 1, wherein a width of the first global bit line in the second direction is equal to or greater than a width of the first bit line in the second direction.

4. The 3D semiconductor device of claim 1, wherein a bottom surface of the first via is a same distance from the bottom surface of the substrate in the first direction as a bottom surface of the first global bit line, and
wherein a thickness of the first via is greater than a thickness of the first global bit line in the first direction.

5. The 3D semiconductor device of claim 1, wherein a width of a bottom surface of the first via in the second direction is equal to or less than a width of the second global bit line in the second direction.

6. The 3D semiconductor device of claim 1, wherein a width of a top surface of the first via in the second direction is equal to or less than a width of the second global bit line in the second direction.

7. The 3D semiconductor device of claim 1, further comprising an air gap between the first via and the first global bit line.

8. The 3D semiconductor device of claim 1, wherein the first via is overlapped by the second bit line and the second global bit line in the first direction.

9. The 3D semiconductor device of claim 1, wherein a distance between the first global bit line and the first via in the second direction is equal to or less than a distance between the first bit line and the second bit line in the second direction.

10. The 3D semiconductor device of claim 1, wherein the bit lines further comprise a third bit line, which extends in the first direction and is spaced apart from the first and second bit lines in the second direction,
wherein the 3D semiconductor device further comprises a third global bit line on the third bit line, and
wherein a distance from the bottom surface of the substrate in the first direction to a top surface of the third global bit line is different from the distance from the bottom surface of the substrate in the first direction to the top surface of the first global bit line and is different from the distance from the bottom surface of the substrate in the first direction to the top surface of the second global bit line.

11. The 3D semiconductor device of claim 10, wherein a distance from the bottom surface of the substrate in the first direction to a bottom surface of the third global bit line is equal to or greater than the distance from the bottom surface of the substrate in the first direction to the top surface of the second global bit line.

12. The 3D semiconductor device of claim 10, further comprising a second via between the third bit line and the third global bit line,
wherein a distance from the bottom surface of the substrate to a bottom surface of the second global bit line and a distance from the bottom surface of the substrate to a top surface of the second global bit line is between a distance from the bottom surface of the substrate to a bottom surface of the second via and a distance from the bottom surface of the substrate to a top surface of the second via in the first direction.

13. The 3D semiconductor device of claim 12, wherein a thickness of the second via is greater than a thickness of the first via in the first direction.

14. A three-dimensional (3D) semiconductor device, comprising:
a substrate;
bit lines on the substrate, extending in a first direction perpendicular to a bottom surface of the substrate, and comprising a first bit line and a second bit line, which are spaced apart from each other in a second direction parallel to the bottom surface of the substrate,
semiconductor patterns on the bit lines and extending in a third direction perpendicular to the first and second directions;
word lines enclosing a portion of the semiconductor patterns and extending in the second direction;
a first global bit line on the first bit line and extending in the third direction;
a second global bit line on the second bit line and extending in the third direction; and
a via between the second bit line and the second global bit line and overlapped by the second bit line and the second global bit line in the first direction,
wherein the via is a same distance from the bottom surface of the substrate in the first direction as a distance to the first global bit line and is adjacent to the first global bit line in the second direction, and
a distance from the bottom surface of the substrate in the first direction of a top surface of the via is greater than a distance from the bottom surface of the substrate in the first direction of a top surface of the first global bit line.

15. The 3D semiconductor device of claim 14, wherein the via has a width that is less than a width of the first global bit line in the second direction.

16. The 3D semiconductor device of claim 14, further comprising:
a protection layer between the first global bit line and the via; and
an air gap in the protection layer.

17. A three-dimensional (3D) semiconductor device, comprising:
a substrate;
a first stack and a second stack, on the substrate and adjacent to each other in a first direction parallel to a bottom surface of the substrate, wherein each of the first and second stacks comprises:
bit lines extending in a second direction perpendicular to the bottom surface of the substrate and spaced apart from each other in a third direction perpendicular to the first and second directions,
semiconductor patterns on the bit lines and are extending in the first direction; and
word lines enclosing a portion of the semiconductor patterns and extending in the third direction,
a data storage pattern between the first stack and the second stack;
global bit lines extending in the first direction and electrically connecting at least one of the bit lines of the first stack to at least one of the bit lines of the second stack, wherein the global bit lines spaced apart from each other in the third direction,
wherein the global bit lines comprise:
first global bit lines; and
second global bit lines, wherein top surfaces of the second global bit lines are at a different distance from the bottom surface of the substrate in the first direction than from top surfaces of the first global bit lines,
wherein at least one of the first global bit lines is adjacent to at least one of the second global bit lines in the third direction, and
a distance from the bottom surface of the substrate in the first direction to a top surface of the data storage pattern is greater than a distance from the bottom surface of the substrate in the first direction to top surfaces of the word lines.

18. The 3D semiconductor device of claim 17, wherein respective distances from the bottom surface of the substrate in the first direction to bottom surfaces of the second global bit lines are greater than respective distances from the bottom surface of the substrate in the first direction to the top surfaces of the first global bit lines.

19. The 3D semiconductor device of claim 17, wherein the global bit lines are arranged in a zigzag shape in a plan view.

20. The 3D semiconductor device of claim 17, wherein the bit lines have a first pitch,
wherein the first global bit lines have a second pitch, and
wherein the first pitch is less than the second pitch.
